(19) United States
(12) Patent Application Publication
(10) Pub. No.: US 2025/0279387 A1
(43) Pub. Date: Sep. 4, 2025

(54) Display Device

(71) Applicant: LG Display Co., Ltd., Seoul (KR)

(72) Inventors: Byonghoo Kim, Paju-si (KR); JuHyuk Kim, Goyang-si (KR); HyoKyeong Son, Seoul (KR); Minwan Kim, Paju-si (KR)

(21) Appl. No.: 18/949,853

(22) Filed: Nov. 15, 2024

(30) Foreign Application Priority Data
Feb. 29, 2024 (KR) 10-2024-0029834

(51) Int. Cl. H01L 23/00; H01L 25/16; H01L 33/60

(52) U.S. Cl. CPC H01L 24/32; H01L 24/29; H01L 25/167; H10H 20/856; H01L 2224/29021; H01L 2224/2919; H01L 2224/3207

(57) ABSTRACT

Provided is a display device. The display device includes a substrate comprising a plurality of subpixels; a thin-film transistor on the substrate; a bonding layer on the thin-film transistor; a first area and a second area having a higher tangent delta value than the first area; and a plurality of light-emitting elements disposed in the first area of the bonding layer corresponding to the plurality of subpixels. The invention allows suppressing a bonding defect of a light-emitting element.

### CROSS-REFERENCE TO RELATED APPLICATIONS

This application claims the priority under 35 U.S.C. § 119 (a) to the Republic of Korea Patent Application No. 10-2024-0029834, filed in the Republic of Korea on Feb. 29, 2024, the entire contents of which are hereby expressly incorporated by reference into the present application.

### BACKGROUND

### Technical Field

The present specification relates to a display device and a method of manufacturing said device, and more particularly, to the display device in which a bonding defect of a light-emitting element (light-emitting diode) is suppressed.

### Description of the Related Art

As display devices used for a monitor of a computer, a TV set, a mobile phone, and the like, there are an organic light-emitting display (OLED) configured to autonomously emit, and a liquid crystal display (LCD) that requires a separate light source.

The range of applications of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, has excellent luminous efficiency, high impact resistance, and great stability, and display high-brightness images.

### SUMMARY

An aspect of the present invention is to suppress a transfer defect from occurring during a process of transferring a light-emitting element to a display panel.

Another aspect of the present invention is to improve a bonding force between a light-emitting element and a bonding layer.

Still another aspect of the present invention is to provide a display device capable of having an excellent transfer yield and allowing a stamp to be used multiple times.

Aspects of the present invention are not limited to the above-mentioned aspects, and other aspects, which are not mentioned above, can be clearly understood by those skilled in the art from the following descriptions.

A display device according to an embodiment of the present specification includes: a substrate including a plurality of subpixels; a thin-film transistor disposed on the substrate; a bonding layer disposed on the thin-film transistor and including a first area, and a second area having a higher tangent delta value than the first area; and a plurality of light-emitting elements disposed in the first area of the bonding layer corresponding to the plurality of subpixels, wherein the tangent delta value is a dimensionless value. In some embodiments, the tangent value is obtained by dividing the indentation hardness value when calculated in N/mm² by the indentation modulus value when calculated in MPa. According to an aspect of the present disclosure, a difference between the tangent delta value of the second area and the tangent delta value of the first area may be 0.05 or greater, preferably, 0.06 or greater, 0.07 or greater, 0.08 or greater, 0.09 or greater, 0.10 or greater, 0.11 or greater, 0.12 or greater, 0.13 or greater, 0.15 or greater, 0.17 or greater. According to an aspect of the present disclosure, a difference between the tangent delta value of the second area and the tangent delta value of the first area may be 0.20 or less, for example, 0.19 or less, or 0.18 or less.

In some embodiments, a display device is provided, the device comprising: a substrate comprising a plurality of subpixels; a thin-film transistor disposed on the substrate; a bonding layer comprising one or more sub-patterns and disposed on the thin-film transistor; and a plurality of light-emitting elements disposed on the bonding layer corresponding to the plurality of subpixels, wherein the sub-patterns of the bonding layer have a lower tangent delta value than an average tangent delta value of the whole bonding layer, and the plurality of light-emitting elements are aligned with the sub-patterns of the bonding layer, and wherein the tangent delta value is a dimensionless value. In certain embodiments, the tangent value is obtained by dividing the indentation hardness value when calculated in N/mm² by the indentation modulus value when calculated in MPa.

Other detailed matters of the exemplary embodiments are included in the detailed description and the drawings.

According to the present specification, it is possible to eliminate a defect in which the light-emitting element is transferred to an undesired area during the process of transferring the light-emitting element.

According to the present specification, it is possible to reduce an erroneous transfer of the light-emitting element and improve a process yield.

According to the present specification, it is possible to remarkably reduce a problem in which a bonding force between the light-emitting element and the bonding layer is degraded or the boundary of the light-emitting element is visually recognized by a void caused by a concave-convex pattern formed on the bottom surface of the light-emitting element.

The effects according to the present disclosure are not limited to the contents exemplified above, and more various effects are included in or can be understood by those skilled in the art.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic configuration view of a display device according to an embodiment.

FIG. 2 is a cross-sectional view of the display device according to the embodiment.

FIG. 3 is a schematic cross-sectional view for explaining a display device according to another embodiment.

FIG. 4 is a process flowchart for explaining a method of manufacturing the display device according to the embodiment.

FIGS. 5A to 5D are process cross-sectional views for explaining the method of manufacturing the display device according to the embodiment.

FIGS. 6A and 6B are images of cross-sections between bonding layers and light-emitting elements of Comparative Embodiment 1 and Embodiment 1.

FIGS. 7A and 7B are images for evaluating transfer defects of Comparative Embodiment 1 and Embodiment 1.

### DETAILED DESCRIPTION OF THE EMBODIMENT

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the inventions of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

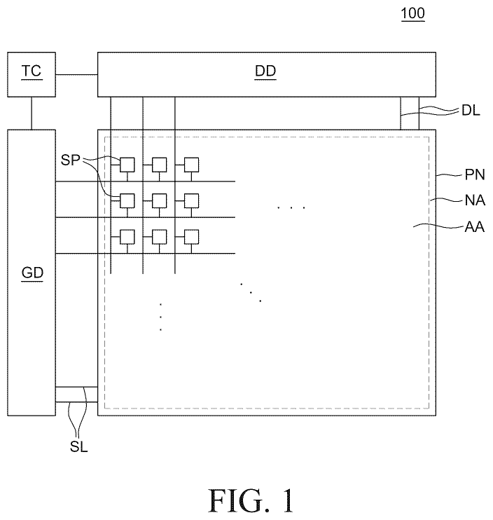

FIG. 1 is a schematic configuration view of a display device according to an embodiment of the present specification. For convenience of description, FIG. 1 illustrates only a display panel PN, a gate driver GD, a data driver DD, and a timing controller TC among various constituent elements of a display device 100.

With reference to FIG. 1, the display device 100 includes the display panel PN including a plurality of subpixels SP, the gate driver GD configured to supply various types of signals to the display panel PN, and the timing controller TC configured to control the data driver DD, the gate driver GD, and the data driver DD.

The gate driver GD supplies a plurality of scan signals to a plurality of scan lines SL in response to a plurality of gate control signals provided from the timing controller TC. FIG. 1 illustrates that the single gate driver GD is disposed to be spaced apart from one side of the display panel PN However, the number and arrangement of the gate driver GD are not limited thereto.

The data driver DD converts image data, which are inputted from the timing controller TC, into a data voltage by using a reference gamma voltage in response to a plurality of data control signals provided from the timing controller TC. The data driver DD may supply the converted data voltage to a plurality of data lines DL.

The timing controller TC aligns image data, which are inputted from the outside, and supplies the image data to the data driver DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate driver GD and the data driver DD by supplying the generated gate control signals and data control signals to the gate driver GD and the data driver DD.

The display panel PN is configured to display images to a user and includes the plurality of subpixels SP. In the display panel PN, the plurality of scan lines SL, and the plurality of data lines DL intersect one another, and each of the plurality of subpixels SP is connected to the scan line SL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include a plurality of subpixels SP constituting a plurality of pixels, and a circuit configured to operate the plurality of subpixels SP. The plurality of subpixels SP is minimum units that constitute the display area AA. The n subpixels SP may constitute a single pixel. A light-emitting element, a thin-film transistor for operating the light-emitting element, and the like may be disposed in each of the plurality of subpixels SP. The plurality of light-emitting elements may be differently defined depending on the type of the display panel PN. For example, in case that the display panel PN is an inorganic light-emitting display panel, the light-emitting element may be a light-emitting diode (LED) or a micro light-emitting diode (micro LED).

A plurality of lines for transmitting various types of signals to the plurality of subpixels SP is disposed in the display area AA. For example, the plurality of lines may include the plurality of data lines DL for supplying data voltages to the plurality of subpixels SP, and the plurality of scan lines SL for supplying scan signals to the plurality of subpixels SP. The plurality of scan lines SL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present specification is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate driver ICs and data driver ICs.

However, the non-display area NA may be positioned on a rear surface of the display panel PN, i.e., a surface on which the subpixel SP is not present. Alternatively, the non-display area NA may be excluded. However, the present specification is not limited to the configuration illustrated in the drawings.

Meanwhile, the drivers such as the gate driver GD, the data driver DD, and the timing controller TC may be connected to the display panel PN in various ways. For example, the gate driver GD may be mounted in the non-display area NA by a gate-in-panel (GIP) method or mounted between the plurality of subpixels SP by a gate-in-active area (GIA) method in the display area AA. For example, the data driver DD and the timing controller TC may be formed on a separate flexible film and the printed circuit board. The data driver DD and the timing controller TC may be electrically connected to the display panel PN by bonding the flexible film and the printed circuit board to the pad electrode formed in the non-display area NA of the display panel PN.

In case that the gate driver GD is mounted by the GIP method and the data driver DD and the timing controller TC transmit signals to the display panel PN through the pad electrode in the non-display area NA, it is necessary to ensure an area of the non-display area NA at a predetermined level or higher in order to dispose the gate driver GD and the pad electrode, which may increase a bezel.

Alternatively, in case that the gate driver GD is mounted in the display area AA by the GIA method and a side line, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. That is, in case that the gate driver GD, the data driver DD, and the timing controller TC are connected to the display panel PN by the above-mentioned method, a zero bezel in which the bezel is not substantially present may be implemented.

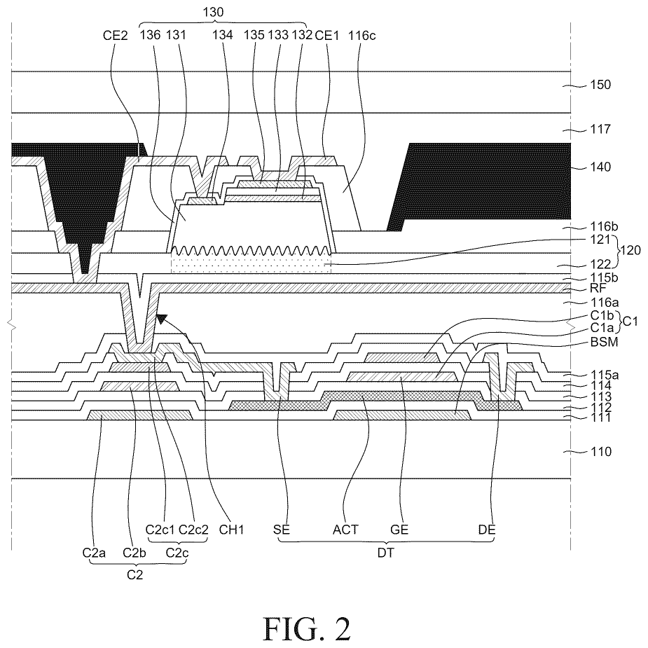

FIG. 2 is a cross-sectional view of the display device according to the embodiment of the present specification.

A substrate 110 may be a substrate, i.e., an insulation substrate configured to support the constituent elements disposed at an upper side of the display device 100. The plurality of subpixels SP may be formed on the substrate 110 so that images may be displayed. For example, the substrate 110 may be made of glass, resin, or the like. In addition, the substrate 110 may include polymer or plastic. In several embodiments, the substrate 110 may be made of a plastic material having flexibility.

A pixel circuit for operating the light-emitting element is disposed in each of the plurality of subpixels SP on the substrate 110. The pixel circuit may include a plurality of thin-film transistors and a plurality of capacitors. For convenience of description, FIG. 2 illustrates only a driving transistor DT, a first capacitor C1, and a second capacitor C2 among the components of the pixel circuit. However, the pixel circuit may further include a switching transistor, a sensing transistor, a light emission control transistor, and the like. However, the present specification is not limited thereto.

First, a light-blocking layer BSM is disposed on the substrate 110. The light-blocking layer BSM may block light entering active layers ACT of the plurality of transistors, thereby minimizing a leakage current. For example, the light-blocking layer BSM may be disposed below the active layer ACT of the driving transistor DT and block light entering the active layer ACT. If the light is emitted to the active layer ACT, a leakage current occurs, which may degrade the reliability of the transistor. Therefore, the light-blocking layer BSM for blocking light may be disposed on the substrate 110, thereby improving the reliability of the driving transistor DT. The light-blocking layer BSM may be made of an opaque electrically conductive material, such as, for example, copper (Cu), aluminum (Al), molybdenum (Mo), nickel (Ni), titanium (Ti), chromium (Cr), or an alloy thereof. However, the present specification is not limited thereto.

A buffer layer 111 is disposed on the light-blocking layer BSM. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present specification is not limited thereto. However, the buffer layer 111 may be excluded in accordance with the type of substrate 110 or the type of thin-film transistor. However, the present specification is not limited thereto.

The driving transistor DT including the active layer ACT, a gate electrode GE, a source electrode SE, and a drain electrode DE is disposed on the buffer layer 111.

First, the active layer ACT of the driving transistor DT is disposed on the buffer layer 111. The active layer ACT may be made of a semiconductor material such as an oxide semiconductor, amorphous silicon, or polysilicon. However, the present specification is not limited thereto. In addition, although not illustrated in the drawings, in addition to the driving transistor DT, other transistors, such as a switching transistor, a sensing transistor, and a light emission control transistor, may be additionally disposed. The active layers of these transistors may be made of a semiconductor material such as an oxide semiconductor, amorphous silicon, or polysilicon. However, the present specification is not limited thereto. In addition, the active layers of the transistors, such as the driving transistor DT, the switching transistor, the sensing transistor, and the light emission control transistor, which are included in the pixel circuits, may be made of the same material or different materials.

The gate insulation layer 112 is disposed on the active layer ACT. The gate insulation layer 112 may be an insulation layer for electrically insulating the active layer ACT and the gate electrode GE. The gate insulation layer 112 may be configured as a single layer or multilayer made of silicon oxide (SiOx) or silicon nitride (SiNx). However, the present specification is not limited thereto.

The gate electrode GE is disposed on the gate insulation layer 112. The gate electrode GE may be made of an electrically conductive material, such as, for example, copper (Cu), aluminum (Al), molybdenum (Mo), nickel (Ni), titanium (Ti), chromium (Cr), or an alloy thereof. However, the present specification is not limited thereto.

A first interlayer insulation layer 113 and a second interlayer insulation layer 114 are disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 are insulation layers for protecting components disposed below the first interlayer insulation layer 113 and the second interlayer insulation layer 114. The first interlayer insulation layer 113 and the second interlayer insulation layer 114 may each be configured as a single layer or multilayer made of silicon oxide (SiOx) or silicon nitride (SiNx). However, the present specification is not limited thereto.

The source electrode SE and the drain electrode DE are disposed on the second interlayer insulation layer 114 and electrically connected to the active layer ACT. The source electrode SE is connected to the second capacitor C2 and a first electrode 134 of a light-emitting element 130, and the drain electrode DE is connected to another component of the pixel circuit. The source electrode SE and the drain electrode DE may each be made of an electrically conductive material, such as, for example, copper (Cu), aluminum (Al), molybdenum (Mo), nickel (Ni), titanium (Ti), chromium (Cr), or an alloy thereof. However, the present specification is not limited thereto.

Next, the first capacitor C1 is disposed on the gate insulation layer 112 The first capacitor C1 includes a first-first capacitor electrode C1a and a first-second capacitor electrode C1b.

First, the first-first capacitor electrode C1a is disposed on the gate insulation layer 112. The first-first capacitor electrode C1a may be integrated with the gate electrode GE of the driving transistor DT.

The first-second capacitor electrode C1b is disposed on the first interlayer insulation layer 113. The first-second capacitor electrode C1b is disposed to overlap the first-first capacitor electrode C1a with the first interlayer insulation layer 113 interposed therebetween.

Therefore, the first capacitor C1 may be connected to the gate electrode GE of the driving transistor DT and maintain the voltage of the gate electrode GE of the driving transistor DT for a predetermined period.

Next, the second capacitor C2 is disposed on the substrate 110. The second capacitor C2 includes a second-first capacitor electrode C2a, a second-second capacitor electrode C2b, and a second-third capacitor electrode C2c. The second capacitor C2 includes the second-first capacitor electrode C2a, which is a lower capacitor electrode, the second-second capacitor electrode C2b, which is an intermediate capacitor electrode, and the second-third capacitor electrode C2c that is an upper capacitor electrode.

The second-first capacitor electrode C2a is disposed on the substrate 110. The second-first capacitor electrode C2a may be disposed on the same layer and made of the same material as the light-blocking layer BSM.

The second-second capacitor electrode C2b is disposed on the buffer layer 111 and the gate insulation layer 112. The second-second capacitor electrode C2b may be disposed on the same layer and made of the same material as the gate electrode GE.

The second-third capacitor electrode C2c is disposed on the first interlayer insulation layer 113. The second-third capacitor electrode C2c may include a first layer C2c1 and a second layer C2c2. The first layer C2cl of the second-third capacitor electrode C2c may be disposed on the same layer and made of the same material as the first-second capacitor electrode C1b. The first layer C2cl may be disposed to overlap the second-first capacitor electrode C2a and the second-second capacitor electrode C2b with the first interlayer insulation layer 113 interposed therebetween.

The second layer C2c2 of the second-third capacitor electrode C2c is disposed on the second interlayer insulation layer 114. The second layer C2c2 is a portion extending from the source electrode SE of the driving transistor DT, and the second layer C2c2 may be connected to the first layer C2c1 through the contact hole of the second interlayer insulation layer 114.

Therefore, the second capacitor C2 may be electrically connected between the light-emitting element 130 and the source electrode SE of the driving transistor DT and increase the inherent capacitance of the light-emitting element 130, such that the light-emitting element 130 may emit light with higher brightness.

The first passivation layer 115a is disposed on the driving transistor DT, the first capacitor C1, and the second capacitor C2. The first passivation layer 115a may be an insulation layer for protecting components disposed below the first passivation layer 115a. The first passivation layer 115a may be made of an inorganic material such as silicon oxide (SiOx) or silicon nitride (SiNx). However, the present specification is not limited thereto.

The first planarization layer 116a is disposed on the first passivation layer 115a. The first planarization layer 116a may planarize an upper portion of the pixel circuit including the driving transistor DT. The first planarization layer 116a may be configured as a single layer or a multilayer and may be made of benzocyclobutene or an acrylic-based organic material, for example. However, the present specification is not limited thereto.

The plurality of reflective plates RF is disposed on the first planarization layer 116a. The reflective plate RF may be configured to reflect the light, which is emitted from the plurality of light-emitting elements 130, toward the upper side of the substrate 110, and may have a shape corresponding to each of the plurality of subpixels SP. One reflective plate RF may be disposed to cover most of the area of one subpixel SP. The reflective plate RF may be electrically connected to the source electrode SE and the second capacitor C2 of the driving transistor DT through a first contact hole CH1 of the first planarization layer 116a and the first passivation layer 115a. Therefore, the reflective plate RF may be electrically connected to the driving transistor DT and the first electrode 134 of the light-emitting element 130. The reflective plate RF may also be used as an electrode that may reflect the light emitted from the light-emitting element 130 and electrically connect the light-emitting element 130 and the pixel circuit. Therefore, the reflective plate RF may include various conductive layers in consideration of light reflection efficiency and resistance. For example, the reflective plate RF may be made by using an opaque conductive layer, which is made of silver (Ag), aluminum (Al), molybdenum (Mo), titanium (Ti), or an alloy thereof, together with a transparent conductive layer made of indium tin oxide (ITO). However, the structure of the reflective plate RF is not limited thereto.

A second passivation layer 115b is disposed on the plurality of reflective plates RF. The second passivation layer 115b may be an insulation layer for protecting components disposed below the second passivation layer 115b. The second passivation layer 115b may be configured as a single layer or multilayer made of silicon oxide (SiOx) or silicon nitride (SiNx). However, the present specification is not limited thereto.

A bonding layer 120 is disposed on the second passivation layer 115b. The bonding layer 120 may be formed on the front surface of the substrate 110 and fix the light-emitting element 130 disposed on the bonding layer 120. The bonding layer 120 may insulate the light-emitting element 130 and the reflective plate RF made of a metallic material. The bonding layer 120 may be disposed to overlap the reflective plate RF disposed in each of the plurality of subpixels SP. The bonding layer 120 may be disposed in each of the plurality of subpixels SP and divided to overlap the reflective plate RF. However, the bonding layer 120 may be disposed on the entire second passivation layer 115b. In addition, the bonding layer 120 may be formed on the front surface of the substrate 110, except for a plurality of pad areas on which a first pad electrode is to be disposed.

The bonding layer 120 includes a first area 121 corresponding to the light-emitting element 130, and a second area 122 that does not correspond to the light-emitting element 130. The first area 121 is an area bonded to the light-emitting element 130 and has a bonding force sufficient to be bonded to the light-emitting element 130. The second area 122 is an area that is not bonded to the light-emitting element 130. The second area 122 has a lower bonding force than the first area 121.

The first area 121 has a low tangent delta value (tan δ), and the second area 122 has a high tangent delta value. The tangent delta value (tan δ) refers to a balance of plasticity with respect to elasticity of the bonding layer 120. More specifically, the tangent delta value (tan δ) may be defined as indentation hardness (HIT, N/mm²)/indentation modulus (EIT, MPa). According to an embodiment of one aspect of the present invention, it is preferable that the bonding layer comprises a polymer material, and more preferably, the bonding layer is mainly formed of a polymer material. According to an embodiment of one aspect of the present invention, the tangent delta value (tan δ) may be a dimensionless value obtained by dividing the indentation hardness value when calculated in N/mm² by the indentation modulus value when calculated in MPa. According to an embodiment of one aspect of the present invention, the indentation hardness (HIT) may be represented as indentation hardness for a depth of several tens to hundreds nm from a surface of the bonding layer 120. The indentation hardness (HIT) may be related to plasticity between elasticity and plasticity of the bonding layer 120. The indentation modulus (EIT) may represent an indentation modulus for a depth of several tens to hundreds nm from a surface of the bonding layer 120. The indentation modulus (EIT) may be related to elasticity between elasticity and plasticity of the bonding layer 120. Meanwhile, the indentation hardness (HIT) and the indentation modulus (EIT) may be measured on the basis of the ISO 14577 standard by means of a nano-indenter.

Specifically, a tangent delta value of the first area 121 may be 0.01 or less, 0.009 or less, 0.008 or less, 0.007 or less, 0.006 or less, or 0.005 or less, and a tangent delta value of the first area 121 may be 0.001 or more, 0.002 or more, 0.003 or more, 0.004 or more, or 0.005 or more, or may be, e.g., any value in the range of 0.001 to 0.008. A tangent delta value of the second area 122 may be 0.05 or more, 0.06 or more, 0.07 or more, 0.08 or more, 0.1 or more, 0.12 or more, or 0.15 or more, and a tangent delta value of the second area 122 may be 0.2 or less, 0.18 or less, 0.15 or less, or may be, e.g., any value in the range of 0.08 to 0.2. In case that the tangent delta values of the first area 121 and the second area 122 satisfy the above-mentioned ranges, the bonding force of the first area 121 is improved, the bonding force of the second area 122 is remarkably reduced in comparison with the first area 121, and the surface becomes robust. Therefore, it is possible to inhibit the light-emitting element 130 from being transferred to an undesired area, i.e., the second area 122.

The bonding layer 120 may be made of a photocurable bonding material that may be cured by ultraviolet rays. For example, the bonding layer 120 may be made of an acrylic-based material including a photosensitive agent. In this case, the first area 121 and the second area 122 of the bonding layer 120 may be made of the same bonding composition. For example, the first area 121 and the second area 122 may be formed by applying the same bonding composition onto the substrate and then partially emitting ultraviolet rays.

More specifically, the bonding layer 120 may include a binder resin, a functional monomer, and a photosensitive agent. For example, the binder resin may be acrylic resin. In addition, the photosensitive agent may be one or more selected from oxime-based and benzophenone-based photoinitiators. Meanwhile, the functional monomer controls adhesiveness of the bonding layer 120 and adjusts the tangent delta value (tan δ). Specifically, the functional monomer includes a low-tangent delta monomer A (first functional monomer) and a high-tangent delta monomer B (second functional monomer).

Specifically, the low-tangent delta monomer A (first functional monomer) means a monomer which can form a surface with a lower tangent delta relative to the high-tangent delta monomer B (second functional monomer). According to an embodiment of one aspect of the present invention, the low-tangent delta monomer A may be a low-molecular weight monomer with high fluidity and may improve a transfer process yield of the light-emitting element 130 by improving adhesiveness of the first area 121. For example, the low-tangent delta monomer A may include one or more selected from a group consisting of diurethane dimethacrylate, polyethylene glycol dimethacrylate, bisphenol A (EO) 10 diacrylate, bisphenol A (EO) 30 diacrylate, tricyclodecane dimethanol diacrylate, tetraethylene glycol diacrylate, polyethylene glycol 200 diacrylate, polyethylene glycol 300 diacrylate, polyethylene glycol 400 diacrylate, polyethylene glycol 600 diacrylate, polyethylene glycol 1000 diacrylate, tris (2-hydroxyethyl) isocyanurate diacrylate, butylated hydroxyanisole, 2,6-di-tert-butyl-4-hydroxymethylphenol, butylated hydroxytoluene, propyl gallate, lauryl gallate, octyl gallate, 2,4,5-trihydroxybutyrophenone, tert-butylhydroquinone 3-aminophenol, 4-aminophenol, 4-methoxyphenol, 2,3,5-trimethylphenol, 2,4-dimethylphenol, 2,6-dimethylphenol, poly (4-vinylphenol), and 4-bromophenol. However, the present specification is not limited thereto.

The high-tangent delta monomer B (second functional monomer) refers to a monomer which can form a surface with a higher tangent delta relative to the low-tangent delta monomer A (first functional monomer). According to an embodiment of one aspect of the present invention, in case that the bonding layer 120 is irradiated with ultraviolet rays, the high-tangent delta monomer B may improve the tangent delta value (tan δ) and make the properties of the film surface robust, thereby inhibiting the light-emitting element 130 from being transferred to the second area 122 during the process of transferring the light-emitting element 130. For example, the high-tangent delta monomer B may include one or more selected from a group consisting of 1,4-butanediol diacrylate, 1,6-hexanediol diacrylate, 1,3-butylene glycol diacrylate, neopentyl glycol diacrylate, ethylene glycol diacrylate, diethylene glycol diacrylate, propylene glycol dimethacrylate, pentaerythritol tetraacrylate, diacrylate, pentaerythritol triacrylate, pentaerythritol dipentaerythritol triacrylate, dipentaerythritol pentaacrylate, pentaerythritol hexaacrylate, triethylene glycol diacrylate, polyethylene glycol diacrylate, dipentaerythritol diacrylate, sorbitol triacrylate, bisphenol A diacrylate derivatives, and trimethylpropanetriacrylate. However, the present specification is not limited thereto.

A content ratio between the low-tangent delta monomer A and the high-tangent delta monomer B may be 3:1 to 1:1, e.g., 2.5:1, 2:1, or 1.5:1. In case that the content of the low-tangent delta monomer A and the content of the high-tangent delta monomer B satisfy the above-mentioned ranges, the bonding force of the first area 121 may be ensured, the bonding force of the second area 122 may be reduced, and the plasticity may be improved. Therefore, during the subsequent process of transferring the light-emitting element 130, a yield of the transfer of the light-emitting element 130 to the first area 121 may be improved, and the light-emitting element 130 may be inhibited from being transferred to the second area 122.

Meanwhile, the content of the functional monomer including the low-tangent delta monomer A and the high-tangent delta monomer B may be 10 to 75, 10 to 70, 20 to 65, 20 to 60, e.g., 20, 30, 40, 50, or 60 parts by weight based on 100 parts by weight of the binder resin. In case that the content of the functional monomer deviates from the above-mentioned range based on the binder resin, the bonding force of the second area 122 may increase, or the bonding force of the first area 121 may decrease.

The first area 121 and the second area 122 of the bonding layer 120 may be formed by selectively irradiating the bonding layer 120 with ultraviolet rays. For example, in case that a partial area of the bonding layer 120 is irradiated with ultraviolet rays, the tangent delta value (tan δ) is improved due to the high-tangent delta monomer B, and the plasticity of the film surface is improved. Therefore, the area irradiated with ultraviolet rays defines the second area 122 to which the light-emitting element 130 is not transferred later. Meanwhile, the area, which is not irradiated with ultraviolet rays, defines the first area 121. The first area 121 has a lower tangent delta value (tan δ) due to the low-tangent delta monomer A than the second area 122, and the bonding force is improved. A specific method of forming the first area 121 and the second area 122 of the bonding layer 120 will be described below.

Meanwhile, the first area 121 and the second area 122 of the bonding layer 120 may be made of different bonding compositions. For example, the first area 121 may include only the low-tangent delta monomer A as the functional monomer, and the second area 122 may include only the high-tangent delta monomer B as the functional monomer. That is, the first area 121 may be made of a first composition including the binder resin, the low-tangent delta monomer A, and the photosensitive agent, and the second area 122 may be made of a second composition including the binder resin, the high-tangent delta monomer B, and the photosensitive agent.

Widths of the first and second areas 121 and 122 of the bonding layer 120 may be determined in consideration of a size and a process margin of the light-emitting element 130. For example, the widths of the first and second areas 121 and 122 may be 20 to 200 μm or 50 to 150 μm. However, the present specification is not limited thereto. Meanwhile, thicknesses of the first and second areas 121 and 122 of the bonding layer 120 may be 2 to 5 μm. However, the present specification is not limited thereto. In addition, as described below, the first area 121, in which the light-emitting element 130 is disposed, may have a larger thickness than the second area 122.

A top surface of the first area 121 of the bonding layer 120 may have a shape further protruding toward the light-emitting element 130 than a top surface of the second area 122. The first area 121 has a structure further protruding upward than the second area 122, such that the light-emitting element 130 may be transferred with a higher yield during the process of transferring the light-emitting element 130 to the display panel and pressing the light-emitting element 130.

Meanwhile, the display device according to another embodiment of the present specification may further include a stepped structure that allows the first area 121 of the bonding layer 120 to have a protruding shape.

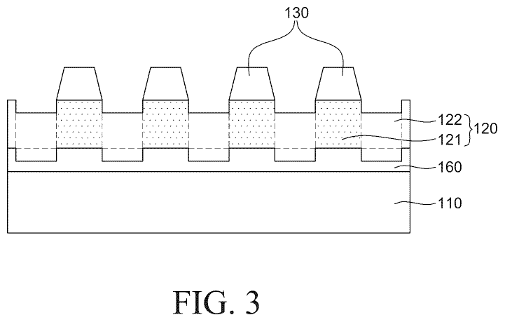

FIG. 3 is a schematic cross-sectional view for explaining a display device according to another embodiment of the present specification. With reference to FIG. 3, a stepped structure 160 is disposed below the bonding layer 120 and includes protruding portions protruding toward the light-emitting elements 130. The stepped structure 160 may be disposed to be in contact with the bonding layer 120. In order to define the protruding portion corresponding to the first area 121, the top surface of the first area 121 may further protrude upward than the top surface of the second area 122. With the stepped structure 160, the light-emitting element 130 may be transferred to the first area 121 of the bonding layer 120 with a higher yield. The stepped structure 160 may be positioned on the reflective plate RF and positioned below the light-emitting element 130. The stepped structure 160 may be formed by using the second passivation layer 115b. In addition, the stepped structure 160 may be formed between the second passivation layer 115b and the bonding layer 120 or positioned between the second passivation layer 115b and the reflective plate RF.

The plurality of light-emitting elements 130 is provided on the bonding layer 120 and disposed in each of the plurality of subpixels SP. The light-emitting elements 130 may be elements configured to emit light by the current and include a red light-emitting element configured to emit red light, a green light-emitting element configured to emit green light, and a blue light-emitting element configured to emit blue light. A combination of the light-emitting elements 130 may implement various colors including white. For example, the light-emitting element 130 may be a light-emitting diode (LED) or a microLED. However, the present specification is not limited thereto.

The light-emitting elements may be respectively connected to the driving transistors DT of the subpixels and operate individually.

The plurality of light-emitting elements 130 include a first semiconductor layer 131, a light-emitting layer 132, a second semiconductor layer 133, the first electrode 134, and a second electrode 135.

The first semiconductor layer 131 is disposed on the bonding layer 120, and the second semiconductor layer 133 is disposed on the first semiconductor layer 131. The first semiconductor layer 131 and the second semiconductor layer 133 may each be a layer formed by doping a particular material with n-type and p-type impurities. For example, the first semiconductor layer 131 and the second semiconductor layer 133 may each be a layer formed by doping a material, such as gallium nitride (GaN), indium aluminum phosphide (InAlP), or gallium arsenide (GaAs) with n-type and p-type impurities. Further, the p-type impurity may be magnesium (Mg), zinc (Zn), beryllium (Be), or the like. The n-type impurity may be silicon (Si), germanium, tin (Sn), or the like. However, the present specification is not limited thereto.

A plurality of concave-convex patterns may be formed on a bottom surface of the first semiconductor layer 131 that is in contact with the bonding layer 120. The concave-convex pattern may be formed on the bottom surface of the first semiconductor layer 131 during a process of manufacturing the light-emitting element 130 and a process of primarily transferring the light-emitting element 130 to a donor substrate.

The light-emitting layer 132 is disposed between the first semiconductor layer 131 and the second semiconductor layer 133. The light-emitting layer 132 may emit light by receiving positive holes and electrons from the first semiconductor layer 131 and the second semiconductor layer 133. The light-emitting layer 132 may be configured as a single layer or a multi-quantum well (MQW) structure. For example, the light-emitting layer 132 may be made of indium gallium nitride (InGaN), gallium nitride (GaN), or the like. However, the present specification is not limited thereto.

The first electrode 134 is disposed on the first semiconductor layer 131. The first electrode 134 is an electrode that electrically connects the driving transistor DT and the first semiconductor layer 131. In this case, the first semiconductor layer 131 may be a semiconductor layer doped with n-type impurities, and the first electrode 134 may be a cathode. The first electrode 134 may be disposed on a top surface of the first semiconductor layer 131 exposed from the light-emitting layer 132 and the second semiconductor layer 133. The first electrode 134 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

The second electrode 135 is disposed on the second semiconductor layer 133. The second electrode 135 may be disposed on a top surface of the second semiconductor layer 133 The second electrode 135 is an electrode that electrically connects the high-potential power line and the second semiconductor layer 133. In this case, the second semiconductor layer 133 may be a semiconductor layer doped with p-type impurities, and the second electrode 135 may be an anode. The second electrode 135 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present specification is not limited thereto.

Next, an encapsulation film 136 is disposed to surround the first semiconductor layer 131, the light-emitting layer 132, the second semiconductor layer 133, the first electrode 134, and the second electrode 135. The encapsulation film 136 may be made of an insulating material and protect the first semiconductor layer 131, the light-emitting layer 132, and the second semiconductor layer 133. Further, a contact hole, through which the first electrode 134 and the second electrode 135 are exposed, may be formed in the encapsulation film 136, such that the first connection electrode CE1, the second connection electrode CE2, the first electrode 134, and the second electrode 135 may be electrically connected.

Meanwhile, a part of a side surface of the first semiconductor layer 131 may be exposed from the encapsulation film 136. The light-emitting element 130 manufactured on a wafer may be separated from the wafer and transferred to the display panel PN. However, a part of the encapsulation film 136 may be torn during a process of separating the light-emitting element 130 from the wafer. For example, a part of the encapsulation film 136 adjacent to a lower edge of the first semiconductor layer 131 of the light-emitting element 130 may be torn during the process of separating the light-emitting element 130 from the wafer, such that a part of a lower side surface of the first semiconductor layer 131 may be exposed to the outside. However, even though the lower portion of the light-emitting element 130 is exposed from the encapsulation film 136, the first connection electrode CE1 and the second connection electrode CE2 are formed after second and third planarization layers 116b and 116c, which cover the side surface of the first semiconductor layer 131, are formed, thereby reducing a short circuit defect.

Next, the second planarization layer 116b and the third planarization layer 116c are disposed on the bonding layer 120 and the light-emitting element 130. The second planarization layer 116b may partially overlap the side surfaces of the plurality of light-emitting elements 130 and fix and protect the plurality of light-emitting elements 130. The third planarization layer 116c may be formed to cover an upper portion of the second planarization layer 116b and an upper portion of the light-emitting element 130. A contact hole, through which the first electrode 134 and the second electrode 135 of the light-emitting element 130 are exposed, may be formed in the third planarization layer 116c. The first electrode 134 and the second electrode 135 of the light-emitting element 130 may be exposed from the third planarization layer 116c. The third planarization layer 116c is partially disposed in an area between the first electrode 134 and the second electrode 135, thereby reducing a short circuit defect. The second planarization layer 116b and the third planarization layer 116c may each be configured as a single layer or multilayer and made of a photoresist or an acrylic-based organic material, for example. However, the present specification is not limited thereto.

Meanwhile, the third planarization layer 116c may cover only the light-emitting element 130 and an area adjacent to the light-emitting element 130. The third planarization layer 116c may be disposed in an area of the subpixel SP surrounded by a bank 140 and disposed in the form of an island. Therefore, the bank 140 may be disposed on a part of a top surface of the second planarization layer 116b, and the third planarization layer 116c may be disposed on another part of the top surface of the second planarization layer 116b.

The first connection electrode CE1 and the second connection electrode CE2 are disposed on the third planarization layer 116c. The first connection electrode CE1 is an electrode that electrically connects the high-potential power line and the second electrode 135 of the light-emitting element 130. The first connection electrode CE1 may be electrically connected to the second electrode 135 of the light-emitting element 130 through the contact hole formed in the third planarization layer 116c.

The second connection electrode CE2 is an electrode that electrically connects the driving transistor DT and the first electrode 134 of the light-emitting element 130. The second connection electrode CE2 may be connected to the reflective plate RF of each of the plurality of subpixels SP through the contact holes formed in the third planarization layer 116c, the second planarization layer 116b, the bonding layer 120, and the second passivation layer 115b. In this case, because the reflective plate RF is also connected to the source electrode SE of the driving transistor DT, the source electrode SE of the driving transistor DT and the first electrode 134 of the light-emitting element 130 may be electrically connected to each other.

Meanwhile, the drawings illustrate that the first electrode 134, the second connection electrode CE2, and the reflective plate RF are electrically connected to the source electrode SE of the driving transistor DT. However, the first electrode 134, the second connection electrode CE2, and the reflective plate RF may be connected to the drain electrode DE of the driving transistor DT. However, the present specification is not limited thereto.

The bank 140 is disposed on the first connection electrode CE1, the second connection electrode CE2, and the second planarization layer 116b exposed from the third planarization layer 116c. The bank 140 may be disposed to be spaced apart from the light-emitting element 130 at a predetermined interval. For example, the bank 140 may be disposed on the second planarization layer 116b with a predetermined interval from the light-emitting element 130. Alternatively, the bank 140 may cover a part of the second connection electrode CE2 formed in the contact holes of the third planarization layer 116c and the second planarization layer 116b. The bank 140 may be made of an opaque material, for example, black resin including a black component to reduce a color mixture between the plurality of subpixels SP. However, the present specification is not limited thereto.

A protective layer 117 is disposed on the first connection electrode CE1, the second connection electrode CE2, and the bank 140. The protective layer 117 is a layer for protecting components disposed below the protective layer 117. The protective layer 117 may be configured as a single layer or multilayer. For example, the protective layer 117 may be made of benzocyclobutene, light transmissive epoxy, a photoresist, or an acrylic-based organic material. However, the present specification is not limited thereto.

An optical film 150 is disposed on the protective layer 117. The optical film 150 may be a functional film that implements images with higher image quality while protecting the display device 100. For example, the optical film 150 may include an anti-scattering film, an anti-glare film, an anti-reflecting film, a low-reflecting film, an OLED transmittance controllable film, or a polarizing plate. However, the present specification is not limited thereto.

Hereinafter, a method of manufacturing the display device according to the embodiment of the present specification will be described.

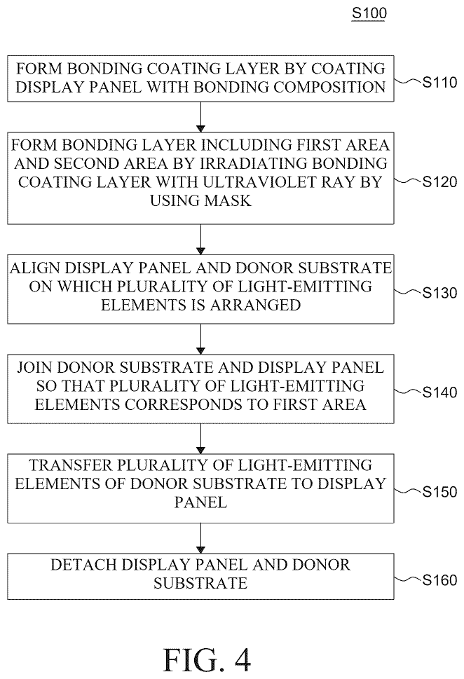

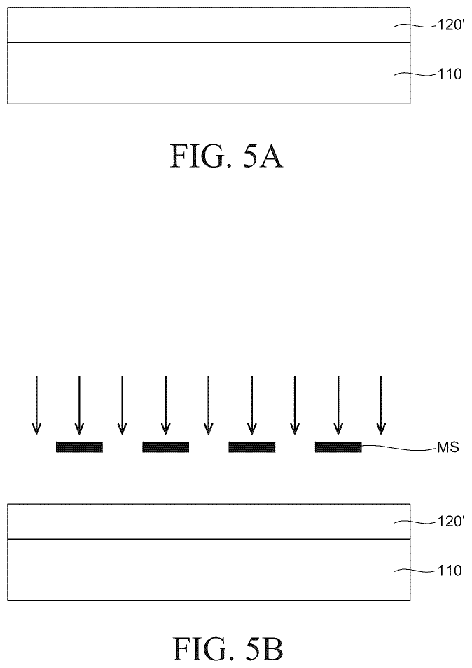

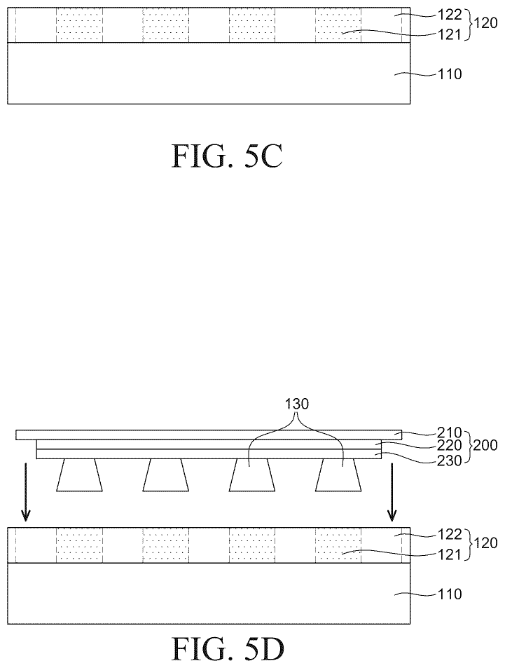

FIG. 4 is a process flowchart for explaining a method of manufacturing the display device according to the embodiment of the present specification. FIGS. 5A to 5D are process cross-sectional views for explaining the method of manufacturing the display device according to the embodiment.

With reference to FIG. 4, a method S100 of manufacturing the display device according to the embodiment of the present specification includes a step S110 of forming a bonding coating layer by coating the display panel with a bonding composition, a step S120 of forming the bonding layer including the first area and the second area by irradiating the bonding coating layer with ultraviolet rays by using a mask, a step S130 of aligning the display panel and the donor substrate on which the plurality of light-emitting elements is arranged, a step S140 of joining the donor substrate and the display panel so that the plurality of light-emitting elements corresponds to the first area, a step S150 of transferring the plurality of light-emitting elements of the donor substrate to the display panel, and a step S160 of detaching the display panel and the donor substrate.

First, with reference to FIG. 5A, a bonding coating layer 120′ is formed by coating the display panel with the bonding composition (S110). In this case, the bonding composition includes a photocurable bonding material and includes the low-tangent delta monomer A and the high-tangent delta monomer B as described above. The method of applying the bonding composition may use a general bonding agent coating method such as spin coating and printing. However, the present specification is not limited thereto.

With reference to FIG. 5B, the bonding layer including the first area and the second area is formed by irradiating the bonding coating layer 120′ with ultraviolet rays by using a mask MS (S120). The bonding force and the tangent delta value (tan δ) may be adjusted by irradiating an area of the bonding coating layer 120′, which corresponds to the second area 122 in which the light-emitting element 130 is not disposed, with ultraviolet rays.

More specifically, with reference to FIG. 5C, a bonding force of the area, which is irradiated with ultraviolet rays through the mask MS when the compound, which constitutes the bonding coating layer 120′, is irradiated with ultraviolet rays as illustrated in FIG. 5B, is reduced, and the tangent delta value (tan δ) is improved, such that the second area 122, to which the light-emitting element 130 is not transferred, is formed later. Therefore, the bonding layer 120 including the first area 121 and the second area 122 may be formed by the step of irradiating the bonding coating layer with ultraviolet rays by using the mask MS.

With reference to FIG. 5D, the display panel and a donor substrate 200, on which the plurality of light-emitting elements 130 is arranged, are aligned (S130). First, the donor substrate 200 on which the plurality of light-emitting elements 130 is arranged is provided. The donor substrate 200 includes a base layer 210, an adhesive layer 220, and a resin layer 230. The base layer 210 may be configured to support various constituent elements included in the donor substrate 200. The base layer 210 may be at least made of a more rigid material than the resin layer 230 to minimize a warp of the resin layer 230. The adhesive layer 220 attaches the resin layer 230 and the base layer 210 by adhesion. For example, the adhesive layer 220 may be an optical clear adhesive (OCA), a pressure sensitive adhesive (PSA), or the like. However, the present specification is not limited thereto. The adhesive layer 220 may be excluded in accordance with design. However, the present specification is not limited thereto. The resin layer 230 includes an area to which the plurality of light-emitting elements 130 formed on the wafer is primarily transferred. The resin layer 230 may be made of polymer resin with viscoelasticity.

The display panel and the donor substrate 200, on which the plurality of light-emitting elements 130 is arranged, are loaded into a process device, and the donor substrate 200 and the display panel, which are loaded into the process device, are aligned so that the donor substrate 200 and the display panel face each other. In this case, the display panel is a display panel on which circuits, e.g., the driving transistors and a plurality of lines for operating the plurality of light-emitting elements 130 are completely formed. In addition, the display panel is a display panel on which the bonding layer 120 including the first area 121 and the second area 122 is completely formed on the circuit. A plurality of alignment keys may be formed on the display panel and aligned with a plurality of alignment marks formed on the donor substrate. Therefore, the donor substrate 200 and the display panel are aligned so that at least some of the plurality of light-emitting elements 130 of the donor substrate 200 correspond to the first area 121 of the bonding layer 120 formed on the top surface of the display panel.

The donor substrate 200 and the display panel are joined so that the plurality of light-emitting elements 130 corresponds to the first area 121 (S140). The display panel and the donor substrate 200 are joined while the state in which the display panel and the donor substrate 200 are completely aligned is maintained.

Thereafter, the plurality of light-emitting elements 130 of the donor substrate 200 is transferred to the display panel (S150). In the state in which the display panel and the donor substrate 200 are joined so that the display panel and the donor substrate 200 face each other, only the light-emitting element 130, which is to be transferred to the display panel among the plurality of light-emitting elements 130, may be selectively irradiated with laser beams. The light-emitting element 130, which is irradiated with laser beams, may be detached from the donor substrate 200 and transferred to the first area 121 of the bonding layer 120 formed on the top surface of the display panel.

Thereafter, the display panel and the donor substrate 200 are detached, and the donor substrate 200, from which the light-emitting element 130 is transferred, is unloaded from the process device (S160).

In general, the display device including the light-emitting element, such as an LED, is manufactured by a process of transferring or stamping the display element of the donor substrate to the display panel on which the driving element and the bonding layer are formed. However, in the case of a small-scale light-emitting element such as a microLED, there is a problem in that the light-emitting element is not properly transferred because of a small size of the light-emitting element. Further, because the picked-up donor substrate cannot be used multiple times, the existing donor substrate needs to be detached after the transferring or stamping process, and another temporary substrate needs to be loaded. For this reason, there is a problem in that the process is complicated. Furthermore, bonding layers with locally different bonding forces are used to bond the display element to a particular position during the process of transferring the display element. In this case, there may occur a problem in that the display element is not sufficiently attached to a desired transfer position, or the display element is attached to an undesired position.

The display device according to the embodiment of the present specification includes the bonding layer including the first and second areas corresponding to the light-emitting element. In this case, the first area is an area having a low tangent delta value and bonded to the light-emitting element, and the second area is an area that has a higher tangent delta value than the first area and is not bonded to the light-emitting element. The bonding layer with these properties may reduce an erroneous process, which attaches the light-emitting element to an undesired area and improve a process yield.

Meanwhile, with reference to FIG. 2, the plurality of concave-convex patterns may be formed on the bottom surface of the light-emitting element. The concave-convex pattern is formed by a process of cutting a semiconductor layer grown on a wafer or primarily transferring the semiconductor layer to the donor substrate during the process of manufacturing the light-emitting element. The concave-convex pattern formed on the bottom surface of the light-emitting element causes a decrease in bonding force with the bonding layer during a process of secondarily transferring the light-emitting element from the donor substrate to the display panel. In case that the light-emitting element is secondarily transferred to the display panel, the bottom surface of the light-emitting element having the concave-convex pattern comes into direct contact with the bonding layer. In this case, voids may be formed in the concave-convex pattern between the bonding layer and the light-emitting element. The voids formed in the concave-convex pattern greatly decreases the bonding force between the bonding layer and the light-emitting element, which causes a transfer defect of the light-emitting element.

In the case of the bonding layer of the display device according to the embodiment of the present specification, the light-emitting element is disposed in the first area having a low tangent delta value. In this case, the occurrence of voids between the bottom surface of the light-emitting element and the bonding layer may be remarkably reduced.

### EXAMPLES

Hereinafter, the effect of the configuration of the bonding layer will be described more specifically with reference to Examples and Comparative Examples. However, the following embodiments are for exemplifying the present specification, and the scope of the present specification is not limited by the following embodiments.

### Example 1

In Example 1, a bonding composition including 15 parts by weight of acrylic-based copolymer resin as a binder resin, 5 parts by weight of diurethane dimethacrylate as a low-tangent delta monomer A (first functional monomer), 3 parts by weight of pentaerythritol tetraacrylate as a high-tangent delta monomer B (second functional monomer), 0.5 parts by weight of 4,4′-bis(dimethylamino) benzophenone as a photosensitive agent, and 76.5 parts by weight of propylene glycol monomethyl ether acetate as a solvent was prepared. A substrate was coated with the prepared bonding composition with a thickness of 3.5 μm, and the bonding composition was dried for 30 seconds in a vacuum chamber with 40 Pa, additionally dried for 10 seconds on a 90° C. hot plate, and then irradiated with ultraviolet ray with 100 mJ/cm² by using a mask. In this case, the bonding layer was formed in which thicknesses of first and second areas were respectively 3.0 μm and 2.7 μm, and widths of the first and second areas were 100 μm.

### Comparative Example 1

A bonding layer was formed in the same way as Example 1, except that a low-tangent delta monomer and a high-tangent delta monomer were not included in the bonding composition.

### Experimental Example 1—Evaluation of Transfer Performance

Micro LEDs with a width of 20 μm were stamped once on the first areas of the bonding layers according to Embodiment 1 and Comparative Embodiment 1, and then the number of microLEDs transferred to the first area and the number of micro LEDs transferred to the second area were identified. The transfer results are shown in Table 1 below.

### Experimental Example 2—Evaluation of Transfer Characteristics

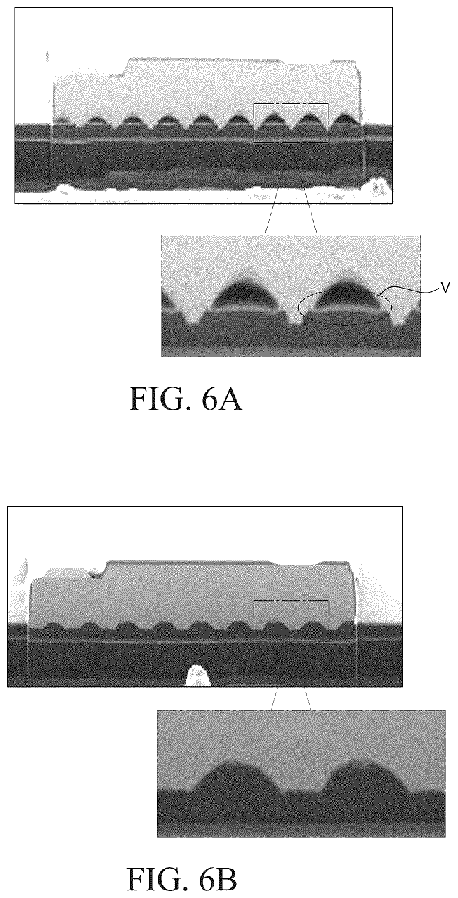

After the process of transferring the microLEDs, images of cross-sections between the bonding layers and the micro LEDs transferred to the first areas were captured by an optical microscope, and the presence or absence of voids formed between the micro LEDs and the bonding layers were identified. FIGS. 6A and 6B are images of cross-sections between bonding layers and light-emitting elements of Comparative Example 1 and Example 1.

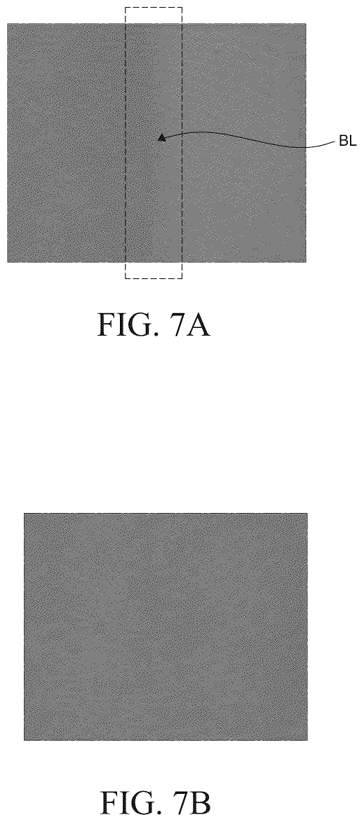

In addition, after the process of transferring the microLEDs, images of areas adjacent to the areas of the top surfaces of the display panels to which the micro LEDs were attached were captured, and whether the concave-convex patterns formed on the bottom surfaces of the micro LEDs were visually recognized were identified. FIGS. 7A and 7B are images for evaluating transfer defects of Comparative Example 1 and Example 1.

TABLE 1

| | Physical property | | | Physical property | | | Transfer | |
|---|---|---|---|---|---|---|---|---|
| | of first area | | | of second area | | | evaluation | |
| | HIT | EIT | Tan | HIT | EIT | Tan | First | Second |
| Classification | (N/mm²) | (MPa) | δ | (N/mm²) | (MPa) | δ | area | area |
| Comparative | 25.2 | 1243.7 | 0.020 | 123.5 | 2450.7 | 0.050 | 18/18 | 10/18 |
| Embodiment 1 | | | | | | | (100%) | (57%) |
| Embodiment 1 | 5.92 | 1071.1 | 0.006 | 146.6 | 1316.6 | 0.106 | 18/18 | 0/18 |
| | | | | | | | (100%) | (0%) |

With reference to Table 1, it may be ascertained that, in comparison with Comparative Example 1, example 1 may eliminate a defect, in which the light-emitting element is erroneously transferred to the second area, such that a process yield is improved. Meanwhile, with reference to FIG. 6A, it may be ascertained that in Comparative Example 1, a plurality of concave-convex patterns was formed on the bottom surface of the light-emitting element in a cross-sectional view, and voids V were formed in the concave-convex pattern between the bonding layer and the light-emitting element. In this case, it may be ascertained that a height of the void with respect to a height of the concave-convex pattern was 46, and a large void was formed in the concave-convex pattern. In contrast, with reference to FIG. 6B, it may be ascertained that in Example 1, substantially no void was formed in the concave-convex pattern between the bonding layer and the light-emitting element, and substantially no void was identified in the images. In this case, it may be ascertained that in comparison with Comparative Example 1, a height of the void with respect to a height of the concave-convex pattern was 3, and a size of the void is remarkably small.

In addition, with reference to FIG. 7A, it may be ascertained that in Comparative Example 1, a luminance difference (8%) was caused on a boundary between the area in which the micro LED was formed and the area in which the micro LED was not formed because of the concave-convex pattern formed on the bottom surface of the micro LED, and a boundary BL of the area in which the micro LED was formed was visually recognized. In contrast, with reference to FIG. 7B, it may be ascertained that in Embodiment 1, a void was insufficiently formed, as identified in FIG. 6B, and the boundary of the area in which the microLED was formed was not recognized with the naked eye.

### Experimental Example 3—Transfer Performance According to Functional Monomer Content

As described below, the transfer performance was evaluated by varying the content of the low-tangent delta monomer and the high-tangent delta monomer that constituted the functional monomer. The evaluation method is identical to that in Experimental Example 1, and the transfer results are shown in Table 2 below.

### Example 2

In Example 2, a bonding layer was formed by a method identical to that in Example 1, except that the content of diurethane dimethacrylate as the low-tangent delta monomer A (first functional monomer) and the content of pentaerythritol tetraacrylate as the high-tangent delta monomer B (second functional monomer) were respectively 2 parts by weight and 1 part by weight.

### Example 3

In Example 3, a bonding layer was formed by a method identical to that in Example 1, except that the content of diurethane dimethacrylate as the low-tangent delta monomer A (first functional monomer) and the content of pentaerythritol tetraacrylate as the high-tangent delta monomer B (second functional monomer) were respectively 4 parts by weight and 2 parts by weight.

### Example 4

In Example 4, a bonding layer was formed by a method identical to that in Example 1, except that the content of diurethane dimethacrylate as the low-tangent delta monomer A (first functional monomer) and the content of pentaerythritol tetraacrylate as the high-tangent delta monomer B (second functional monomer) were respectively 6 parts by weight and 3 parts by weight.

### Comparative Example 2

In Comparative Example 2, a bonding layer was formed by a method identical to that in Example 1, except that only 2 parts by weight of diurethane dimethacrylate as the low-tangent delta monomer A (first functional monomer) was included, and the high-tangent delta monomer B (second functional monomer) was not used.

### Comparative Example 3

In Comparative Example 3, a bonding layer was formed by a method identical to that in Example 1, except that the content of diurethane dimethacrylate as the low-tangent delta monomer A (first functional monomer) and the content of pentaerythritol tetraacrylate as the high-tangent delta monomer B (second functional monomer) were respectively 8 parts by weight and 4 parts by weight.

TABLE 2

| | | | Total content | | |
|---|---|---|---|---|---|
| | | | ratio of | | |
| | Functional monomer | | functional | | |
| | content | | monomer based | Transfer | |
| | A (parts | B (parts | on binder resin | evaluation | |
| | by | by | A + B | First | Second |
| Classification | weight) | weight) | (weight %) | area | area |
| Embodiment 2 | 2 | 1 | 20 | 18/18 | 0/18 |
| | | | | (100%) | (0%) |
| Embodiment 3 | 4 | 2 | 40 | 18/18 | 0/18 |
| | | | | (100%) | (0%) |
| Embodiment 4 | 6 | 3 | 60 | 18/18 | 0/18 |
| | | | | (100%) | (0%) |
| Comparative | 2 | 0 | 13.33 | 18/18 | 10/18 |
| Embodiment 2 | | | | (100%) | (57%) |
| Comparative | 8 | 4 | 80 | 18/18 | 6/18 |
| Embodiment 3 | | | | (100%) | (33%) |

With reference to Table 2, it may be ascertained that the light-emitting element was erroneously transferred even to the second area in case that the high-tangent delta monomer was not included. In addition, it may be ascertained that even though the low-tangent delta monomer and the high-tangent delta monomer were included at the same ratio, the effect of selectively suppressing the transfer to the second area was somewhat degraded in case that the total content of the functional monomer was 70% or more based on the binder resin.

The exemplary embodiments of the present disclosure can also be described as follows:

According to an aspect of the present disclosure, a display device is provided. The display device includes a substrate comprising a plurality of subpixels; a thin-film transistor disposed on the substrate; a bonding layer disposed on the thin-film transistor and comprising a first area, and a second area having a higher tangent delta value than the first area; and a plurality of light-emitting elements disposed in the first area of the bonding layer corresponding to the plurality of subpixels, wherein the tangent delta value is a dimensionless value obtained by dividing the indentation hardness value when calculated in N/mm² by the indentation modulus value when calculated in MPa.

The tangent delta value of the first area may be 0.01 or less, and the tangent delta value of the second area is 0.08 to 0.2.

The second area may be higher in hardness than the first area.

The bonding layer may comprise a binder resin, a photosensitive agent, and first and second functional monomers with different tangent delta values.

The first functional monomer may include one or more selected from a group consisting of diurethane dimethacrylate, polyethylene glycol dimethacrylate, bisphenol A (EO) 10 diacrylate, bisphenol A (EO) 30 diacrylate, tricyclodecane dimethanol diacrylate, tetraethylene glycol diacrylate, polyethylene glycol 200 diacrylate, polyethylene glycol 300 diacrylate, polyethylene glycol 400 diacrylate, polyethylene glycol 600 diacrylate, polyethylene glycol 1000 diacrylate, tris (2-hydroxyethyl) isocyanurate diacrylate, butylated hydroxyanisole, 2,6-di-tert-butyl-4-hydroxymethylphenol, butylated hydroxytoluene, propyl gallate, lauryl gallate, octyl gallate, 2,4,5-trihydroxybutyrophenone, tert-butylhydroquinone 3-aminophenol, 4-aminophenol, 4-methoxyphenol, 2,3,5-trimethylphenol, 2,4-dimethylphenol, 2,6-dimethylphenol, poly (4-vinylphenol), and 4-bromophenol.

The second functional monomer may include one or more selected from a group consisting of 1,4-butanediol diacrylate, 1,6-hexanediol diacrylate, 1,3-butylene glycol diacrylate, neopentyl glycol diacrylate, ethylene glycol diacrylate, diethylene glycol diacrylate, propylene glycol dimethacrylate, pentaerythritol tetraacrylate, pentaerythritol diacrylate, pentaerythritol triacrylate, dipentaerythritol triacrylate, dipentaerythritol pentaacrylate, pentaerythritol hexaacrylate, triethylene glycol diacrylate, polyethylene glycol diacrylate, dipentaerythritol diacrylate, sorbitol triacrylate, bisphenol A diacrylate derivatives, and trimethylpropanetriacrylate.

A total content of the functional monomer including the first functional monomer and the second functional monomer may be 10 to 70 parts by weight based on 100 parts by weight of the binder resin.

A top surface of the first area may further protrude toward the plurality of light-emitting elements than a top surface of the second area.

The display device may further comprise a stepped structure disposed below the bonding layer and comprising a protruding portion protruding toward the plurality of light-emitting elements corresponding to the first area.

The display device may further comprise a planarization layer on the thin-film transistor; a plurality of reflective plates disposed on the planarization layer and respectively connected to the plurality of light-emitting elements; and a passivation layer between the plurality of reflective plates and the bonding layer. The stepped structure may be disposed between the plurality of reflective plates and the passivation layer or disposed between the passivation layer and the bonding layer.

The display device may further comprise a planarization layer on the thin-film transistor; a plurality of reflective plates disposed on the planarization layer and respectively connected to the plurality of light-emitting elements; and a passivation layer between the plurality of reflective plates and the bonding layer. The stepped structure may be formed as the passivation layer.

A concave-convex pattern may be formed on a bottom surface of each of the plurality of light-emitting elements.

A void may be formed between the bonding layer and the concave-convex pattern, and a ratio of a height of the void to a height of the concave-convex pattern may be 5 or less.

All the bottom surfaces of the plurality of light-emitting elements may be in contact with the bonding layer in the first area so that no void is formed between the bonding layer and the concave-convex pattern.

The plurality of light-emitting elements each may comprise a first semiconductor layer on the bonding layer; a second semiconductor layer on the first semiconductor layer; a light-emitting layer between the first semiconductor layer and the second semiconductor layer; a first electrode disposed on the first semiconductor layer and disposed to be spaced apart from the light-emitting layer; and a second electrode on the second semiconductor layer. A bottom surface of the first semiconductor layer may be in direct contact with the first area of the bonding layer.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate comprising a plurality of subpixels;
a thin-film transistor disposed on the substrate;
a bonding layer disposed on the thin-film transistor and comprising a first area, and a second area having a higher tangent delta value than the first area; and
a plurality of light-emitting elements disposed in the first area of the bonding layer corresponding to the plurality of subpixels,
wherein the tangent delta value is a dimensionless value obtained by dividing an indentation hardness value when calculated in N/mm² by an indentation modulus value when calculated in MPa.

2. The display device of claim 1, wherein the tangent delta value of the first area is 0.01 or less, and the tangent delta value of the second area is 0.08 to 0.2.

3. The display device of claim 1, wherein the second area is higher in hardness than the first area.

4. The display device of claim 1, wherein the bonding layer comprises a binder resin, a photosensitive agent, and a first and a second functional monomers, wherein the second functional monomer is capable of forming a surface having a higher tangent delta value than the first functional monomer.

5. The display device of claim 4, wherein the first functional monomer includes one or more compounds selected from a group consisting of diurethane dimethacrylate, polyethylene glycol dimethacrylate, bisphenol A (EO) 10 diacrylate, bisphenol A (EO) 30 diacrylate, tricyclodecane dimethanol diacrylate, tetraethylene glycol diacrylate, polyethylene glycol 200 diacrylate, polyethylene glycol 300 diacrylate, polyethylene glycol 400 diacrylate, polyethylene glycol 600 diacrylate, polyethylene glycol 1000 diacrylate, tris (2-hydroxyethyl) isocyanurate diacrylate, butylated hydroxyanisole, 2,6-di-tert-butyl-4-hydroxymethylphenol, butylated hydroxytoluene, propyl gallate, lauryl gallate, octyl gallate, 2,4,5-trihydroxybutyrophenone, tert-butylhydroquinone 3-aminophenol, 4-aminophenol, 4-methoxyphenol, 2,3,5-trimethylphenol, 2,4-dimethylphenol, 2,6-dimethylphenol, poly (4-vinylphenol), and 4-bromophenol.

6. The display device of claim 4, wherein the second functional monomer includes one or more compounds selected from a group consisting of 1,4-butanediol diacrylate, 1,6-hexanediol diacrylate, 1,3-butylene glycol diacrylate, neopentyl glycol diacrylate, ethylene glycol diacrylate, diethylene glycol diacrylate, propylene glycol dimethacrylate, pentaerythritol tetraacrylate, pentaerythritol diacrylate, pentaerythritol triacrylate, dipentaerythritol triacrylate, dipentaerythritol pentaacrylate, pentaerythritol hexaacrylate, triethylene glycol diacrylate, polyethylene glycol diacrylate, dipentaerythritol diacrylate, sorbitol triacrylate, bisphenol A diacrylate derivatives, and trimethylpropanetriacrylate.

7. The display device of claim 4, wherein a total content of the functional monomer including the first functional monomer and the second functional monomer is 10 to 70 parts by weight based on 100 parts by weight of the binder resin.

8. The display device of claim 1, wherein a top surface of the first area further protrudes toward the plurality of light-emitting elements than a top surface of the second area.

9. The display device of claim 8, further comprising:
a stepped structure disposed below the bonding layer and comprising a protruding portion protruding toward the plurality of light-emitting elements corresponding to the first area.

10. The display device of claim 9, further comprising:
a planarization layer disposed on the thin-film transistor;
a plurality of reflective plates disposed on the planarization layer and respectively connected to the plurality of light-emitting elements; and
a passivation layer between the plurality of reflective plates and the bonding layer,
wherein the stepped structure is disposed between the plurality of reflective plates and the passivation layer is disposed between the passivation layer and the bonding layer.

11. The display device of claim 9, further comprising:
a planarization layer on the thin-film transistor;
a plurality of reflective plates disposed on the planarization layer and respectively connected to the plurality of light-emitting elements; and
a passivation layer disposed between the plurality of reflective plates and the bonding layer,
wherein the stepped structure is formed as the passivation layer.

12. The display device of claim 1, wherein a concave-convex pattern is formed on a bottom surface of each of the plurality of light-emitting elements.

13. The display device of claim 12, wherein a void is formed between the bonding layer and the concave-convex pattern, and a ratio of a height of the void to a height of the concave-convex pattern is 5 or less.

14. The display device of claim 12, wherein each one of the bottom surfaces of the plurality of light-emitting elements is in contact with the bonding layer in the first area so that no void is formed between the bonding layer and the concave-convex pattern.

15. The display device of claim 12, wherein each of the plurality of light-emitting elements comprises:
a first semiconductor layer on the bonding layer;
a second semiconductor layer on the first semiconductor layer;
a light-emitting layer between the first semiconductor layer and the second semiconductor layer;
a first electrode disposed on the first semiconductor layer and disposed to be spaced apart from the light-emitting layer; and
a second electrode on the second semiconductor layer,
wherein a bottom surface of the first semiconductor layer is in direct contact with the first area of the bonding layer.

16. The display device of claim 1, wherein a difference between the tangent delta value of the second area and the tangent delta value of the first area is 0.05 to 0.2.

17. A display device comprising:
a substrate comprising a plurality of subpixels;
a thin-film transistor disposed on the substrate;
a bonding layer comprising one or more sub-patterns and disposed on the thin-film transistor; and
a plurality of light-emitting elements disposed on the bonding layer corresponding to the plurality of subpixels,
wherein the sub-patterns of the bonding layer have a lower tangent delta value than an average tangent delta value of the whole bonding layer, and the plurality of light-emitting elements are aligned with the sub-patterns of the bonding layer, and
wherein the tangent delta value is a dimensionless value obtained by dividing the indentation hardness value when calculated in N/mm² by the indentation modulus value when calculated in MPa.

18. The display device of claim 17, wherein the sub-patterns of the bonding layer have a tangent delta value that is lower than the tangent delta value of another area in the bonding layer by at least 0.05.

19. The display device of claim 17, wherein the bonding layer comprises a binder resin, a photosensitive agent, and a first and a second functional monomers, wherein the second functional monomer is capable of forming a surface having a higher tangent delta value than the first functional monomer, and a total content of the functional monomer including the first functional monomer and the second functional monomer is 10 to 70 parts by weight based on 100 parts by weight of the binder resin.

20. The display device of claim 19, wherein a content ratio between the first functional monomer and the second functional monomer is 3:1 to 1:1.
